(19) United States
(12) Patent Application Publication
(10) Pub. No.: US 2007/0126518 A1
(43) Pub. Date: Jun. 7, 2007

(54) Oscillator using TFMS line

(75) Inventors: Hong Gu Ji, Daejeon (KR); Hea Cheon Kim, Daejeon (KR); Kyoung Ik Cho, Daejeon (KR)

Correspondence Address: MAYER, BROWN, ROWE & MAW LLP, 1909 K STREET, N.W., WASHINGTON, DC, 20006, US

(73) Assignee: ELECTRONICS AND TELECOMMUNICATIONS RESEARCH INSTITUTE

(21) Appl. No.: 11/544,629

(22) Filed: Oct. 10, 2006

(30) Foreign Application Priority Data
Dec. 7, 2005 (KR) 2005-119111
Jun. 30, 2006 (KR) 2006-60388

(51) Int. Cl. H03B 5/18

(52) U.S. Cl. 331/107 SL

(57) ABSTRACT

Provided is an oscillator in which a resonator unit and an oscillator unit are coupled with each other using a thin film microstrip (TFMS) line to increase a line impedance and thus improve a phase noise characteristic. The oscillator includes a resonator unit resonating in a specific frequency band among variable frequencies, an oscillator unit generating an oscillation frequency using the resonance frequency, and a coupling unit coupling the resonator unit with the oscillator unit using a TFMS line.

### CROSS-REFERENCE TO RELATED APPLICATION

This application claims priority to and the benefit of Korean Patent Application Nos. 2005-119111, filed Dec. 7, 2005 and 2006-60388, filed Jun. 30, 2006, the disclosures of which are incorporated herein by reference in their entirety.

### BACKGROUND

1. Field of the Invention

The present invention relates to an oscillator in which a resonator unit and an oscillator unit are coupled with each other using a thin film microstrip (TFMS) line to increase a line impedance, and thus a phase noise characteristic is improved.

2. Discussion of Related Art

Recently, with the rapid development of the wireless communication market, a variety of services are being provided. Thus, high frequency bands on the order of GHz are gradually coming into use, and a design is required for miniaturizing and reducing the weight of wireless communication devices. Consequently, there is a growing tendency to employ a hybrid microwave integrated circuit (MIC) and a microwave monolithic integrated circuit (MMIC).

Among such circuits, an MMIC oscillation circuit of an X-band super high-frequency (SHF) oscillator coupled with a resonator is enabling high integration and unification of manufacturing processes.

However, the oscillator has a drawback in that noise at an oscillation frequency is generated due to a low degree of resonance of the resonator.

In order to solve this problem, a microstrip resonator is used that has an excellent resonance characteristic due to use of a microstrip. Thus, the degree of resonance (unloaded Q) of the resonator increases, enabling a low-noise high-output oscillator to be embodied.

In addition, when the oscillator implemented in the MMIC form is fabricated, a coupling unit couples a resonator unit with an oscillator unit using a line having a high impedance, so that a phase noise characteristic of the oscillator can be improved at around an oscillation frequency. Thus, a technique is used that makes a characteristic impedance line thin to increase its impedance.

FIGS. 1A and 1B are diagrams of a conventional SHF oscillator unit coupled with a resonator unit, and FIG. 1C is a cross-sectional view of a coupling unit shown in FIG. 1B taken along line A-A′.

Referring to FIGS. 1A to 1C, an oscillator comprises a resonator unit 10 resonating in a specific frequency band among variable frequencies, an oscillator unit 30 generating an oscillation frequency using the resonance frequency, and a coupling unit 20 coupling the resonator unit 10 and the oscillator unit 30 using a microstrip line.

As illustrated in FIG. 1C, the coupling unit 20 includes a GaAs substrate 22, a ground 24 formed on one side of the substrate 22, and a microstrip line 28 formed on the other side of the substrate 22.

However, since a characteristic impedance of the coupling unit 20 is proportional to a thickness of the substrate 22, there is a maximum limit to a line's characteristic impedance. In addition, since the substrate 22 should be formed thick in order to increase characteristic impedance, the size of an integrated circuit increases.

### SUMMARY OF THE INVENTION

The present invention is directed to an oscillator in which a resonator unit and an oscillator unit are coupled with each other using a thin film microstrip (TFMS) line to increase a line impedance, and thus a phase noise characteristic is improved.

The present invention is also directed to an oscillator using a TFMS line, having a small size, and thus capable of being used to fabricate a semiconductor integrated circuit.

One aspect of the present invention provides an oscillator using a TFMS line, comprising: a resonator unit resonating in a specific frequency band among variable frequencies; an oscillator unit generating an oscillation frequency using the resonance frequency; and a coupling unit coupling the resonator unit with the oscillator unit using a TFMS line.

The coupling unit may include: a substrate; a ground formed on an upper side of the substrate; a dielectric layer formed of a dielectric material on the ground; and the TFMS line formed on the dielectric layer.

### BRIEF DESCRIPTION OF THE DRAWINGS

The above and other features and advantages of the present invention will become more apparent to those of ordinary skill in the art by describing in detail exemplary embodiments thereof with reference to the attached drawings in which:

FIGS. 1A and 1B are diagrams of a conventional super high frequency (SHF) oscillator unit coupled with a resonator unit;

FIG. 1C is a cross-sectional view of a coupling unit shown in FIG. 1B taken along line A-A′;

FIGS. 2A and 2B are diagrams of an SHF oscillator unit coupled with a resonator unit according to an exemplary embodiment of the present invention;

FIG. 2C is a cross-sectional view of a coupling unit shown in FIG. 2B taken along line B-B′; and

FIG. 3 is a graph showing traces of impedance Zg of a thin film microstrip (TFMS) line and a microstrip line around a resonance frequency.

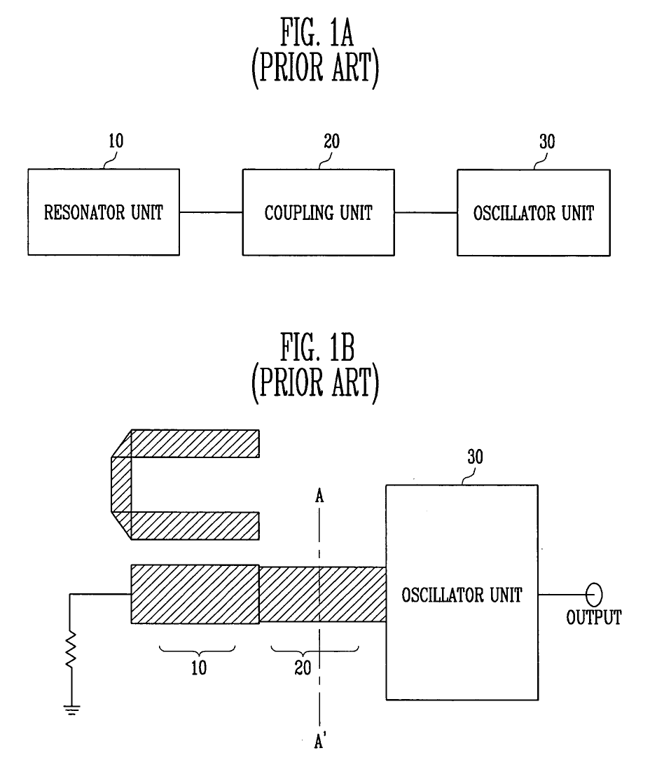

### DETAILED DESCRIPTION OF EXEMPLARY EMBODIMENTS

Hereinafter, exemplary embodiments of the present invention will be described in detail. However, the present invention is not limited to the exemplary embodiments disclosed below and can be implemented in various forms. Therefore, the present exemplary embodiments are provided for complete disclosure of the present invention and to fully inform the scope of the present invention to those of ordinary skill in the art.

Exemplary embodiments of an oscillator using a thin film microstrip (TFMS) line according to the present invention will be described below with reference to the appended drawings.

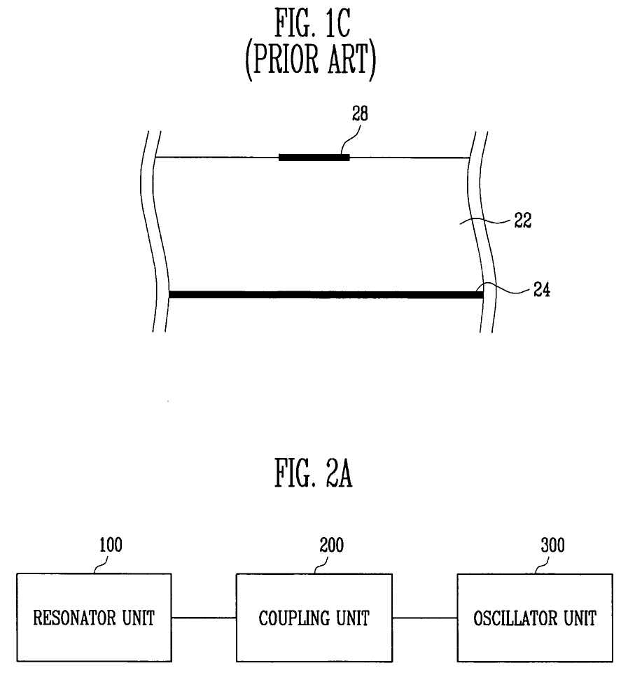

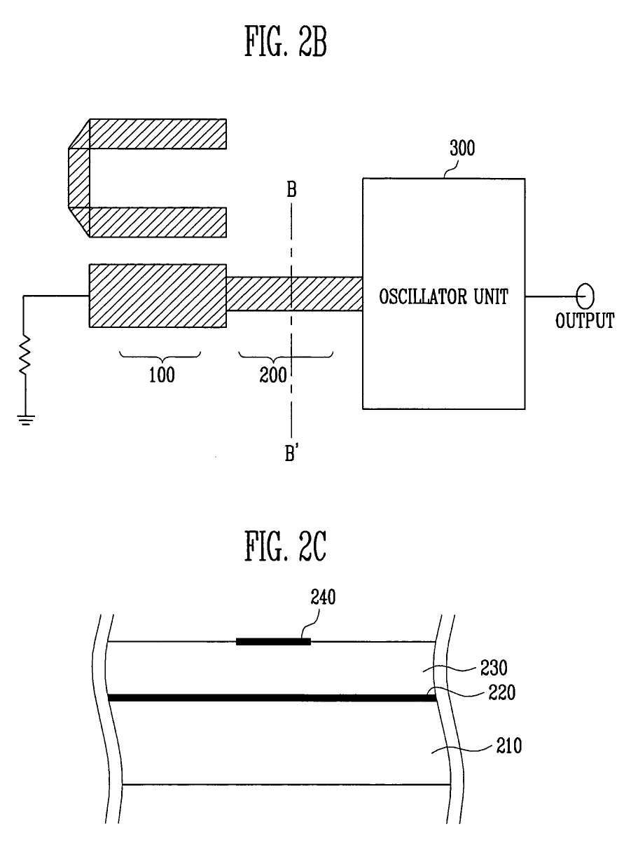

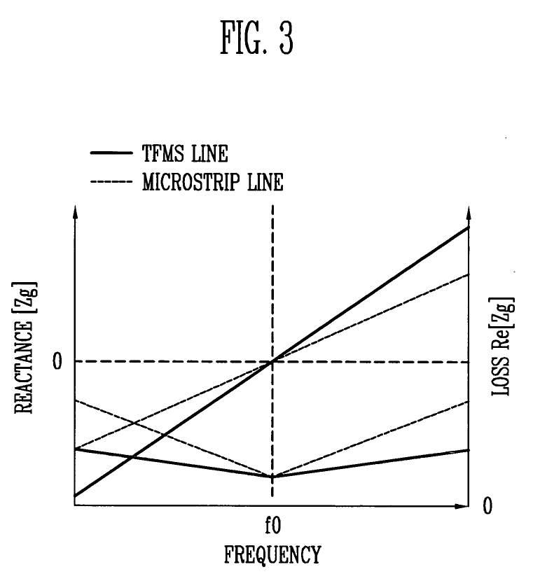

FIGS. 2A and 2B are diagrams of a super high-frequency (SHF) oscillator unit coupled with a resonator unit according to an exemplary embodiment of the present invention, and FIG. 2C is a cross-sectional view of a coupling unit shown in FIG. 2B taken along line B-B′.

Referring to FIGS. 2A to 2C, an oscillator comprises a resonator unit 100 resonating in a specific frequency band among variable frequencies, an oscillator unit 300 generating an oscillation frequency using the resonance frequency; and a coupling unit 200 coupling the resonator unit 100 with the oscillator unit 300 using a TFMS line.

As illustrated in FIG. 2C, the coupling unit 200 includes a GaAs substrate 210, a ground 220 formed on the substrate 210, a dielectric layer 230 formed of a dielectric material on the ground 220, and a TFMS line 240 formed on the dielectric layer 230.

A characteristic impedance of the TFMS line 240 coupled with the resonator unit 100 and the oscillator unit 300 is adjusted so that a reactance component may be abruptly changed. Thus, when the resonant circuit is connected in series with a load including an active element, it increases an external quality factor Q. Consequently, a degree of resonance increases, and phase noise of the oscillator unit 300 decreases.

In addition, the characteristic impedance of the TFMS line 240 is proportional to the thickness of the substrate. When the ground 220 is formed on the substrate 210, the dielectric layer 230 is formed on the ground 220, and then the TFMS line 240 is formed on the dielectric layer 230, the total thickness can be increased by the thickness of the dielectric layer 230. Therefore, it is possible to improve the phase noise characteristic of the oscillator by increasing the characteristic impedance of the TFMS line 240.

FIG. 3 is a graph showing traces of impedance Zg of the TFMS line and a microstrip line around a resonance frequency.

As illustrated in FIG. 3, when a TFMS technique is applied to the coupling unit 200, the characteristic impedance of the TFMS line 240 can increase. More specifically, at an impedance around the resonance frequency, the slope of a reactance Im(Zg) component becomes steep, and the impedance Re(Zg) component, which is a loss component, becomes small.

When the resonant circuit is connected in series with a load including an active element, the external quality factor Q becomes large. Consequently, a degree of resonance becomes large, which means that the phase noise characteristic of the oscillator is improved. In addition, the TFMS technique is good for reducing total size and thus enables a degree of integration to be increased.

As described above, in the oscillator according to the present invention, the TFMS technique is applied to the coupling unit so as to increase a characteristic impedance of a coupling unit line, so that phase noise of the oscillator can be improved.

In addition, the circuit using a TFMS line has a higher degree of integration than a conventional integrated circuit, and thus can be used to fabricate a semiconductor integrated circuit.

While the invention has been shown and described with reference to certain exemplary embodiments thereof, it will be understood by those skilled in the art that various changes in form and details may be made therein without departing from the spirit and scope of the invention as defined by the appended claims.

What is claimed is:

1. An oscillator, comprising:
a resonator unit resonating in a specific frequency band among variable frequencies;
an oscillator unit generating an oscillation frequency using the resonance frequency; and
a coupling unit coupling the resonator unit with the oscillator unit using a thin film microstrip (TFMS) line.

2. The oscillator of claim 1, wherein the coupling unit comprises:
a substrate;
a ground formed on the substrate;
a dielectric layer formed of a dielectric material on the ground; and
the TFMS line formed on the dielectric layer.
